(19) United States
(12) Patent Application Publication
(10) Pub. No.: US 2023/0387372 A1
(43) Pub. Date: Nov. 30, 2023

(54) DISPLAY MODULE INCLUDING MICRO LIGHT EMITTING DIODES

(71) Applicant: SAMSUNG ELECTRONICS CO., LTD., Suwon-si (KR)

(72) Inventors: Yoonsuk LEE, Suwon-si (KR); Eunhye KIM, Suwon-si (KR); Sangmoo PARK, Suwon-si (KR); Jamyeong KOO, Suwon-si (KR); Sera KWON, Suwon-si (KR); Byunghoon LEE, Suwon-si (KR); Changkyu CHUNG, Suwon-si (KR)

(73) Assignee: SAMSUNG ELECTRONICS CO., LTD., Suwon-si (KR)

(21) Appl. No.: 18/205,312

(22) Filed: Jun. 2, 2023

Related U.S. Application Data
(63) Continuation of application No. PCT/KR2023/004735, filed on Apr. 7, 2023.

(30) Foreign Application Priority Data
May 27, 2022 (KR) 10-2022-0065624
Jul. 21, 2022 (KR) 10-2022-0090565

(51) Int. Cl. H01L 33/62; H01L 25/16; H01L 33/58; H01L 23/00

(52) U.S. Cl. CPC H01L 33/62; H01L 25/167; H01L 33/58; H01L 24/29; H01L 24/30; H01L 24/32; H01L 2224/30505; H01L 2224/30517; H01L 2224/3003; H01L 2224/3011; H01L 2224/32145; H01L 2924/12041; H01L 2224/2919; H01L 2224/29111; H01L 2224/29139; H01L 2224/29144; H01L 2224/29147; H01L 2224/29155; H01L 2224/29166; H01L 2924/0132

(57) ABSTRACT

Provided is a display assembly including a plurality of light emitting diodes, a plurality of electrodes provided on the plurality of light emitting diodes, a substrate, a plurality of electrode pads provided on the substrate, the plurality of electrode pads being connected to the electrodes provided on the plurality of light emitting diodes, and an adhesive layer fixing the plurality of light emitting diodes to the substrate, wherein the adhesive layer includes a non-conductive polymer resin, a flux agent mixed with the non-conductive polymer resin, and a plurality of conductive particles dispersed in the non-conductive polymer resin and connecting the electrodes of the light emitting diodes and the plurality of electrode pads.

### CROSS-REFERENCE TO RELATED APPLICATION(S)

This application is a bypass continuation of International Application No. PCT/KR2023/004735, filed on Apr. 7, 2023, in the Korean Intellectual Property Receiving Office, which is based on and claims priority to Korean Patent Application No. 10-2022-0065624, filed on May 27, 2022 and Korean Patent Application No. 10-2022-0090565, filed on Jul. 21, 2022, in the Korean Intellectual Property Office, the disclosures of which are incorporated by reference herein in their entireties.

### BACKGROUND

### 1. Field

Embodiments of the disclosure relate to a display module including a micro light emitting diode.

### 2. Description of Related Art

The display panel includes a substrate provided with a thin film transistor (TFT) and a plurality of light emitting diodes mounted on a substrate.

The plurality of light emitting diodes may be inorganic light emitting diodes that emit light by itself. The plurality of light emitting diodes are operated in units of pixels or sub-pixels and express various colors. Operations of each pixel or subpixel are controlled by a plurality of TFTs. Each light emitting diode emits various colors, e.g., red, green, blue.

### SUMMARY

Embodiments of the disclosure provide a display module having a reliable bonding strength between an electrode of a micro light emitting diode and an electrode pad of a substrate.

According to an aspect of an embodiment, there is provided a display assembly including a plurality of light emitting diodes, a plurality of electrodes provided on the plurality of light emitting diodes, a substrate, a plurality of electrode pads provided on the substrate, the plurality of electrode pads being connected to the electrodes provided on the plurality of light emitting diodes, and an adhesive layer fixing the plurality of light emitting diodes to the substrate, wherein the adhesive layer includes a non-conductive polymer resin, a flux agent mixed with the non-conductive polymer resin, and a plurality of conductive particles dispersed in the non-conductive polymer resin and connecting the electrodes of the light emitting diodes and the plurality of electrode pads.

The flux agent may be made of a material that improves wetting property of the plurality of conductive particles.

The plurality of conductive particles may include a plurality of first conductive particles, and a plurality of second conductive particles having higher wetting property than the plurality of first conductive particles.

The plurality of first conductive particles may include at least one of tin (Sn), silver (Ag), copper (Cu), bismuth (Bi), and cobalt (Co).

A material of the plurality of second conductive particles and one of a material of the electrodes provided on the plurality of light emitting diodes or a material of the plurality of electrode pads provided on the substrate, may be same.

The second conductive particle may be made of one of gold (Au), copper (Cu), and silver (Ag).

The plurality of conductive particles may have size of 10 nm to 1 μm.

The adhesive layer may further include a pigment or dye having a black-based color.

The adhesive layer may be in a film shape.

The adhesive layer may be in a paste shape.

According to another aspect of an embodiment, there is provided a display device including a processor, and a display assembly including a plurality of light emitting diodes, a plurality of electrodes provided on the plurality of light emitting diodes, a substrate, a plurality of electrode pads provided on the substrate, the plurality of electrode pads being connected to the electrodes provided on the plurality of light emitting diodes, and an adhesive layer fixing the plurality of light emitting diodes to the substrate, wherein the adhesive layer includes a non-conductive polymer resin, a flux agent mixed with the non-conductive polymer resin, and a plurality of conductive particles dispersed in the non-conductive polymer resin and connecting the electrodes of the light emitting diodes and the plurality of electrode pads.

The flux agent may be made of a material that improves wetting property of the plurality of conductive particles.

The plurality of conductive particles may include a plurality of first conductive particles, and a plurality of second conductive particles having higher wetting property than the plurality of first conductive particles.

The plurality of first conductive particles may include at least one of tin (Sn), silver (Ag), copper (Cu), bismuth (Bi), and cobalt (Co).

A material of the plurality of second conductive particles and one of a material of the electrodes provided on the plurality of light emitting diodes or a material of the plurality of electrode pads provided on the substrate, may be same.

The second conductive particle may be made of one of gold (Au), copper (Cu), and silver (Ag).

The plurality of conductive particles may have size of 10 nm to 1 μm.

The adhesive layer may further include a pigment or dye having a black-based color.

The adhesive layer may be in a film shape.

The adhesive layer may be in a paste shape.

### BRIEF DESCRIPTION OF DRAWINGS

The above and other aspects, features, and advantages of embodiments of the disclosure will be more apparent from the following description taken in conjunction with the accompanying drawings, in which:

FIG. 1 is a block diagram illustrating a display device according to an embodiment of the disclosure;

FIG. 2 is a plan-view indicating display module according to an embodiment of the disclosure;

FIG. 3 is a schematic cross-sectional view of a pixel provided in a display module according to an embodiment of the disclosure;

FIG. 4 is a diagram illustrating an example of aligning a relay substrate on which a micro light-emitting diode (LED) is arranged with respect to a substrate before transferring the relay substrate to a substrate;

FIG. 5 is a diagram illustrating an example of transferring a micro LED arranged on a relay substrate to a substrate by a laser transfer method;

FIG. 6 is a diagram illustrating an example of thermally compressing a micro LED transferred to a substrate with a pressing member;

FIG. 7 is a schematic cross-sectional view of a pixel provided in a display module according to an embodiment of the disclosure;

FIG. 8 is a schematic cross-sectional view of a pixel provided in a display module according to an embodiment of the disclosure;

FIG. 9 is a schematic cross-sectional view of a pixel provided in a display module according to an embodiment of the disclosure;

FIG. 10 is a schematic cross-sectional view of a pixel provided in a display module according to an embodiment of the disclosure;

FIG. 11 is a schematic cross-sectional view of a pixel provided in a display module according to an embodiment of the disclosure;

FIG. 12 is a diagram illustrating an example of thermally compressing a micro LED transferred to a substrate with a pressing member;

FIG. 13 is a diagram illustrating an example in which first conductive particles and second conductive particles dispersed in an adhesive layer are collected between an electrode of a micro LED and an electrode pad of a substrate to form a solder.

### DETAILED DESCRIPTION

Hereinafter, various embodiments will be described in detail with reference to the accompanying drawings. The embodiments described herein may be variously modified. Specific embodiments are depicted in the drawings and may be described in detail in the description of the disclosure. However, it is to be understood that the particular embodiments disclosed in the appended drawings are for ease of understanding of various embodiments. Therefore, it is intended that the invention not be limited to the particular embodiments disclosed in the accompanying drawings, but on the contrary, the intention is to cover all equivalents or alternatives falling within the spirit and scope of the disclosure.

Terms such as “first,” “second,” and the like may be used to describe various components, but the components should not be limited by the terms. The terms are used to distinguish a component from another.

It is to be understood that the terms such as “comprise” or “consist of” are used herein to designate a presence of a characteristic, number, step, operation, element, component, or a combination thereof, and do not to preclude a presence or a possibility of adding one or more of other characteristics, numbers, steps, operations, elements, components or a combination thereof. It will be understood that when an element is referred to as being “coupled” or “connected” to another element, there may be other elements in the middle, although it may be directly coupled or connected to the other element. In contrast, when an element is referred to as being “directly coupled to” or “directly connected to” another element, there are no elements present therebetween.

In the disclosure, “the same” may refer to components that are matched as well as those that may be different within an extent of the processing error range.

When it is decided that a detailed description for the known art related to the disclosure may unnecessarily obscure the gist of the disclosure, the detailed description may be shortened or omitted.

According to an embodiment of the disclosure, a display module may include a plurality of light-emitting diodes for displaying an image. The display module may include a planar display panel or a curved display panel.

According to an embodiment of the disclosure, the light emitting diode included in a display module may be an inorganic light emitting diode having a size of 100 micrometers or below. For example, the inorganic light emitting diode may be a micro LED or mini LED, but is not limited thereto. The inorganic LED of the disclosure has brightness, luminous efficiency, and lifetime longer than the organic LED (OLED). The inorganic LED may be a semiconductor chip capable of emitting light by itself when power is supplied. The inorganic LED has a fast reaction rate, low power, and high luminance. When the inorganic light emitting diode is a micro LED, the efficiency of converting electricity into a photon in comparison with an LCD or an OLED may be higher. The micro LED may have higher “brightness per Watt” as compared to LCD or OLED displays. The micro LED may provide the same brightness while consuming less about substantially half energy as the LED exceeding 100 μm or OLED. The micro LEDs are capable of providing high resolution, outstanding color, contrast and brightness, may accurately provide a wide range of colors, and may provide a clear screen even in the outdoors brighter than indoors. In addition, the micro LEDs are resistant to burn-in phenomenon, and generate less heat, thereby improving product lifespan without deformation.

According to an embodiment of the disclosure, a light emitting diode may be formed in the form of a flip chip in which an anode and a cathode electrode are disposed on the opposite surface of a light emitting surface.

According to an embodiment of the disclosure, the substrate may be disposed with a thin film transistor (TFT) layer formed of a TFT circuit on a first surface (e.g., the front surface of the substrate), and a power supply circuit to supply power to the TFT circuit and data driving driver, a gate drive driver and a timing controller to control each drive driver may be disposed on a second surface (e.g., rear surface of the substrate). A plurality of pixels may be arranged on a TFT layer. Each pixel may be driven by a TFT circuit.

According to an embodiment, the TFT formed on the TFT layer may be a low-temperature polycrystalline silicon (LTPS) TFT, a low-temperature polycrystalline oxide (LTPO) TFT, or an oxide TFT.

According to an embodiment, the substrate may be a glass substrate, a synthetic resin series having a flexibility material (for example, polyimide (PI), polyethylene terephthalate (PET), polyethersulfone (PES), polyethylene naphthalate (PEN), polycarbonate (PC), etc.) or a ceramic substrate.

According to an embodiment of the disclosure, the TFT layer of the substrate may be integrally formed with the first surface of the substrate or may be manufactured in a separate film form and attached to the first surface of the substrate.

According to an embodiment of the disclosure, a first surface of a substrate may be divided into an active region and an inactive region. The active region may be a region occupied by the TFT layer in the entire region of the first surface of the substrate. The inactive region may be a region other than the active region in the entire region of the first surface of the substrate.

According to an embodiment of the disclosure, an edge region of a substrate may be an outermost region of a substrate. For example, the edge region of the substrate may include a region corresponding to a side surface of the substrate, a partial region of a first surface of the substrate adjacent to the side surface, respectively, and a partial region of the second surface of the substrate. A plurality of side wirings electrically connecting the TFT circuit on the first surface of the substrate and the driving circuit on the second surface of the substrate may be disposed in the edge region of the substrate.

According to an embodiment of the disclosure, a substrate may be formed in a rectangular shape. For example, the substrate may be formed in a rectangle or square.

According to an embodiment, the TFT provided on the substrate may be implemented as, for example, a low temperature poly silicon (LTPS) TFT, an oxide TFT, a poly silicon or a-silicon TFT, an organic TFT, and a graphene TFT, or the like. The TFT may be applied to a P type (or N-type) MOSFET in a Si wafer CMOS process.

According to an embodiment of the disclosure, a substrate included in a display module may omit a TFT layer on which a TFT circuit is formed. In this case, a plurality of micro IC chips functioning as a TFT circuit may be mounted on the first surface of the substrate. The plurality of micro ICs may be electrically connected to a plurality of light emitting diodes arranged on a first surface of the substrate through wirings.

According to an embodiment of the disclosure, a driving scheme of a display module may be an active matrix (AM) or passive matrix (PM).

According to an embodiment, the display module may be installed and applied to wearable devices, portable devices, handheld devices, and electronic products or electronic parts requiring various displays.

According to an embodiment of the disclosure, a display device such as a monitor for a personal computer, a high-resolution television, a signage (or a digital signage), an electronic display, and the like may be formed by connecting a plurality of display modules in a grid array.

According to an embodiment of the disclosure, one pixel may include a plurality of light emitting diodes. In this case, one light emitting diode may be a subpixel. In the disclosure, one “light-emitting diode”, one “micro LED”, and one “sub-pixel” may be interchangeably used.

Hereinbelow, the disclosure will be described in detail with reference to the accompanying drawings so that those skilled in the art can easily implement one embodiment. However, one embodiment of the disclosure may be implemented in various different forms and is not limited to one embodiment described herein. In order to clearly describe the embodiment in the drawings, parts which are not related to the description of the disclosure have been omitted, and like reference numerals refer to similar parts throughout the specification.

Hereinafter, a display module and a display device including the same according to an embodiment of the disclosure will be described with reference to the drawings.

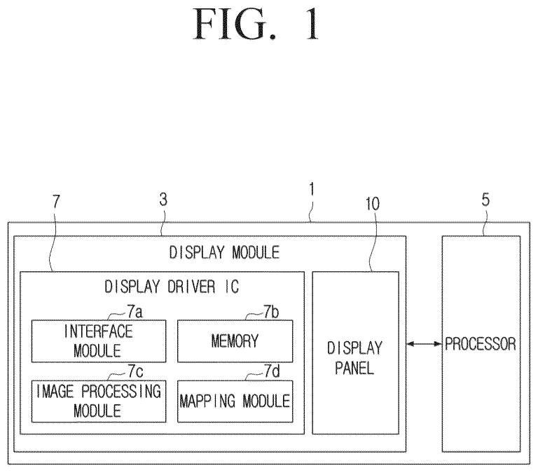

FIG. 1 is a block diagram illustrating a display device according to an embodiment of the disclosure.

Referring to FIG. 1, a display device 1 according to an embodiment may include a display module 3 (display assembly 3) and a processor 5.

The display module 3 according to an embodiment of the disclosure may display various images. Here, the image is a concept including a still image and/or a video. The display module 3 may display various images such as broadcast content, multimedia content, and the like. In addition, the display module 3 may display a user interface and an icon.

The display module 3 may include a display panel 10 and a display driver integrated circuit 7 for controlling the display panel 10.

The display driver integrated circuit (IC) 7 includes an interface module 7a, a memory 7b (e.g., a buffer memory), an image processing module 7c, and a mapping module 7d. The display driver IC 7 may receive image information including image data, or an image control signal corresponding to a command for controlling the image data from another component of the display device 1 through the interface module 7a. For example, the image information may be received from the processor 5 (e.g., a main processor, an application processor (AP)) or the secondary processor 44 (e.g., a graphics processing unit (GPU)) operating independently of the function of the main processor.

The display driver IC 7 may store at least a part of the received image information in the memory 7b, for example, in a frame unit. The image processing module 7c may perform pre-processing or post-processing (e.g., resolution, brightness, or size adjustment) for at least a part of the image data based on at least one of the characteristics of the image data or characteristics of the display panel 10. The mapping module 7d may generate a voltage value or a current value corresponding to the image data pre-processed or post-processed through the image processing module 7c. The generation of a voltage value or current value may be performed based at least in part on an attribute of pixels of the display panel 10 (e.g., an array of pixels (red-green-blue (RGB) stripe or PenTile structure), or a size of each of the subpixels). At least some pixels of the display panel 10 may be driven based at least in part on the voltage value or current value such that visual information (e.g., text, an image, or an icon) corresponding to the image data may be displayed through the display panel 10.

The display driver IC 7 may transmit a driving signal (e.g., driver driving signal, gate driving signal, etc.) to a display based on image information received from the processor 5.

The display driver IC 7 may display an image based on the image signal received from the processor 5. For example, the display driver IC 7 may generate a driving signal of a plurality of sub-pixels based on an image signal received from the processor 5, and display an image by controlling light emission of the plurality of sub-pixels based on the driving signal.

The display module 3 may further include a touch circuit. The touch circuit may include a touch sensor and a touch sensor IC for controlling the touch sensor. The touch sensor IC may control the touch sensor to detect a touch input or hovering input for the designated position of the display panel 10. For example, the touch sensor IC may detect a touch input or hovering input by measuring the change in the signal (e.g., voltage, light amount, resistance, or charge) for the designated position of the display panel 10. The touch sensor IC may provide information about the detected touch input or hovering input (e.g., location, area, pressure, or time) to the processor 5. At least part of the touch circuit 250 (e.g., the touch sensor IC) may be included as part of the display driver IC 7, or as part of the display panel 10, or other components (e.g., a sub-processor) placed outside of the display module 3.

The processor 5 may be implemented with a digital signal processor (DSP) for processing of a digital signal, a microprocessor, a time controller (TCON), or the like. The processor 5 may include one or more among a central processor unit (CPU), a micro controller unit (MCU), a micro processor unit (MPU), a controller, an application processor (AP), a communication processor (CP), an advanced reduced instruction set computing (RISC) machine (ARM) processor, a dedicated processor, or may be defined as a corresponding term. The processor 5 may be implemented in a system on chip (SoC) type or a large scale integration (LSI) type which a processing algorithm is built therein, application specific integrated circuit (ASIC), or in a field programmable gate array (FPGA) type.

The processor 5 may control hardware or software components coupled to the processor 5 by driving an operating system or an application program, and may perform various data processing and operations. Further, the processor 5 may load and process commands or data received from at least one of the other components into the volatile memory and store the various data in the non-volatile memory.

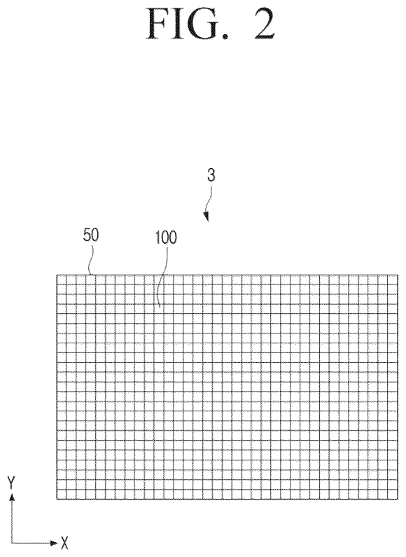

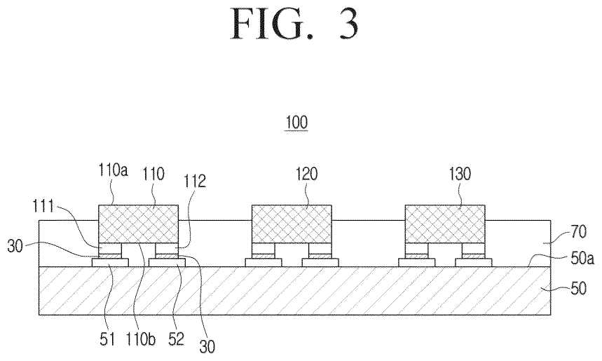

FIG. 2 is a plan-view indicating display module according to an embodiment of the disclosure; FIG. 3 is a schematic cross-sectional view of a pixel provided in a display module according to an embodiment of the disclosure.

Referring to FIG. 2, the display module 3 may include a substrate 50 and a plurality of pixels 100 provided on a first surface of the substrate 50.

The substrate 50 may be provided with a thin film transistor (TFT) circuit electrically connecting the plurality of pixels 100 on the first surface.

A plurality of pixels 100 may each include at least three sub-pixels. The subpixel may be a micro LED, which is an inorganic light emitting diode. Hereinafter, for convenience, the sub-pixel is referred to as a micro LED. Here, the micro LED may be an LED having a size of 100 μm or less. The “size” may be a diameter in a given direction on a plane of a normally mounted micro LED. In one example, the given direction may be a horizontal direction or a vertical direction, and in another example, the given direction may be a direction having a maximum diameter on a plane.

Referring to FIG. 3, a pixel 100 may include a first micro LED 110 emitting light of a red wavelength band, a second micro LED 120 emitting light of a green wavelength band, and a third micro LED 130 emitting light of a blue wavelength band.

The pixel 100 may include a first micro LED 110, a second micro LED 120, and a third micro LED 130 arranged in a pixel area partitioned and spaced apart on a substrate 50. A plurality of TFTs for driving the first to third micro LEDs 110, 120, 130 may be arranged in a region not occupied by the first to third micro LED 110, 120, 130 in the pixel region.

The first to third micro LED 110, 120, 130 may be arranged in a line at regular intervals, but embodiments are not limited thereto. For example, the first to third micro LED 110, 120, 130 may be arranged in an L shape or arranged in a PenTile RGBG method. The PenTile RGBG scheme is a scheme in which red, green, and blue subpixels are arranged at a ratio of 1:1:2 (RGBG) by using a characteristic that a human may better identify a green color than blue color. The PenTile RGBG method may increase yield, and decrease unit cost. The PenTile RGBG may implement higher resolution on a small screen, thereby being more effective.

The light emission characteristics of the first micro LED 110 may be the same as the second and third micro LED 120, 130. Light emitted from the first micro LED 110 may be light having the same color as light emitted from the second and third micro LED 120, 130. In one example, the first to third micro LEDs 110, 120, 130 may all emit blue light, green light, or red light. Accordingly, monochromatic light of red, green, or blue may be emitted from the pixel 100, and light mixed with red, green, or blue may be emitted.

The display module 3 may be, for example, a touch screen coupled with a touch sensor, a flexible display, a rollable display, and/or a three-dimensional (3D) display.

The TFT provided on the substrate 50 may be a substrate like amorphous silicon (a-Si) TFT, low temperature polycrystalline silicon (LTPS) TFT, low temperature polycrystalline oxide (LTPO) TFT, hybrid oxide and polycrystalline silicon (HOP) TFT, liquid crystalline polymer (LCP) TFT, or organic TFT (OTFT).

Referring to FIG. 3, a plurality of electrode pads 51, 52 may be arranged in pairs at intervals on a first surface 50a of the substrate 50. The plurality of electrode pads 51, 52 may be electrically connected to the first to third micro LEDs 110, 120, 130, respectively.

For example, a pair of electrodes 111, 112 provided in the first micro LED 110 may be connected to a pair of electrode pads 51, 52 of the substrate 50. The pair of electrodes 111, 112 may be electrically and physically connected to a pair of electrode pads 51, 52 of the substrate 50 by a solder 30, respectively.

The solder 30 may include, for example, tin (Sn) or indium (In). The solder 30 may include at least two of tin (Sn), silver (Ag), indium (In), copper (Cu), nickel (Ni), gold (Au), bismuth (Bi), aluminum (Al), zinc (Zn), and gallium (Ga).

An adhesive layer 70 may be provided on and covered on a first surface 50a of the substrate 50. The adhesive layer 70 may cover a plurality of electrode pads 51, 52 and the solder 30.

A pair of electrodes 111, 112, each provided with a second micro LED 120 and a third micro LED 130, may be electrically and physically connected to a corresponding pair of electrode pads 51, 52 provided on the substrate 50 by means of the solder 30.

The first micro LED 110 may be in the form of a flip chip. For example, a pair of electrodes 111, 112 may be arranged on a surface 110b of the first micro LED 110 opposite to the light emitting surface 110a. The second micro LED 120 and the third micro LED 130 may be in the form of a flip chip substantially the same as the first micro LED 110. In this case, the sizes of the first to third micro LEDs 110, 120, 130 may all be the same, but embodiments are not limited thereto. For example, at least one of the first to third micro LEDs 110, 120, 130 may be different in size from the others.

The substrate 50 may be provided with electrode pads 51, 52 to which electrodes 111, 112 provided on the first to third micro LED 110, 120, 130 are electrically connected, respectively.

The electrode pads 51, 52 provided on the substrate 50 may be electrically connected to the TFT circuit of the TFT layer through via hole wiring, respectively.

The electrode pads 51, 52 provided on the substrate 50 may be electrically connected to the electrodes 111, 112 provided on the first micro LED 110, respectively. The electrode pads 51 and 52 provided on the substrate 50 may include, for example, titanium/aluminum/titanium (Ti/Al/Ti) alloy, molybdenum/aluminum/molybdenum (Mo/Al/Mo) alloy, nickel/gold (Ni/Au) alloy, indium (In), nickel (Ni), or copper (Cu).

The electrodes 111 and 112 provided on the first micro LED 110 electrically connected to the electrode paddles 51 and 52 provided on the substrate 50 by the solder 30 may be made of a nickel/gold (Ni/Au) alloy, a titanium/gold (Ti/Au) alloy, a copper (Cu), a copper/nickel (Cu/Ni) alloy, or a tin/silver (Sn/Ag) alloy.

The first surface 50a of the substrate 50 may be covered by the adhesive member 70. The adhesive layer 70 may be stacked on the first surface 50a of the substrate 50 before the first to third micro LEDs 110, 120, 130 are transferred to the substrate 50. In this case, the adhesive layer 70 may cover the plurality of electrode pads 51, 52 arranged on the first surface of the substrate 10.

The adhesive layer 70 may include a non-conductive polymer resin and a flux agent. The adhesive layer 70 may be molded as a film shape.

The non-conductive polymer resin may be an insulating polymer resin having thermal curable characteristic or ultraviolet (UV)-curable characteristic.

The non-conductive polymer resin may include, for example, an epoxy-based curable resin composition or an acrylic curable resin composition.

The epoxy-based thermosetting resin composition may include, for example, a compound or resin having two or more epoxy groups in a molecule, an epoxy curing agent, a film-forming component, and the like. The compound or resin having two or more epoxy groups in the molecule may be a liquid or solid phase.

For example, a compound or resin having two or more epoxy groups in a molecule may be a bi-functional epoxy resin such as a bisphenol A type epoxy resin or a bisphenol F type epoxy resin, a novolac type epoxy resin such as a phenol novolac type epoxy resin or a cresol novolac type epoxy resin, and the like.

As the epoxy curing agent, for example, an amine-based curing agent, an imidazole-based curing agent, an acid anhydride-based curing agent, a sulfonium cation-based curing agent, and the like may be used.

As the film forming component, for example, an epoxy compound or an epoxy resin or a phenoxy resin or an acrylic resin used for the epoxy resin may be used.

The acrylic thermosetting resin composition may include, for example, a (meth) acrylate monomer, a resin for forming a film, an inorganic filler such as silica, a silane coupling agent, a radical polymerization initiator, and the like. As the (meth) acrylate monomer, a monofunctional (meth) acrylate monomer, a polyfunctional (meth) acrylate monomer, or a monofunctional or polyfunctional (meth) acrylate monomer in which an epoxy group, a urethane group, an amino group, an ethylene oxide group, a propylene oxide group, and the like are introduced may be used. In addition, another monomer capable of radical copolymerization with a (meth) acrylate monomer, for example, (meth) acrylic acid, vinyl acetate, styrene, vinyl chloride, and the like may be used in combination.

The resin for film formation of acrylic thermosetting resin composition may include a phenoxy resin, a polyvinyl acetal resin, a polyvinyl butyral resin, an alkylated cellulose resin, a polyester resin, an acrylic resin, a styrene resin, a urethane resin, a polyethylene terephthalate resin, and the like.

Examples of the radical polymerization initiator include organic peroxides such as benzoyl peroxide, dicumyl peroxide, dibutyl peroxide and the like, azobisisobutyronitrile, azobisivaleronitrile, and the like.

The acrylic thermosetting resin composition may further include a stress-relaxer such as butadiene rubber or a solvent such as ethyl acetate, a colorant, an antioxidant, an aging inhibitor, and the like as necessary.

The flux agent may be made of a material to improve wetting property of the solder 30 and prevent oxidation of the solder 30.

The flux agent may be, for example, an anhydride capable of producing Lewis acid or a thermal acid generator (TAG) which is decomposed by heating to generate an acid. The anhydride may be selected to include an acyl group. The thermal acid generator may be a sulfite-based compound. The flux agent is not limited thereto and may be an inorganic flux, such as a zinc chloride-based or zinc chloride-chloride ammonia system. The flux agent may be a rosin-based flux, such as an active rosin or an inert rosin. The flux agent may be a water-soluble flux, such as salts, acids, amines. The flux agent may be an organic flux, such as a glutamate hydrochloride and an ethylenediamine stearate hydrochloride.

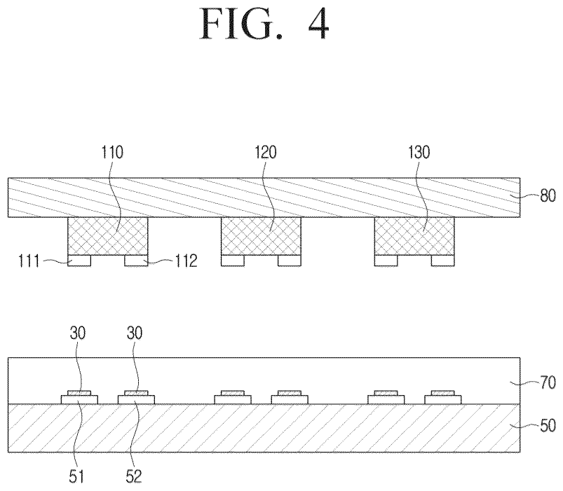

FIG. 4 is a diagram illustrating an example of aligning a relay substrate on which a micro LED is arranged with respect to a substrate before transferring the relay substrate to a substrate.

Referring to FIG. 4, solders 30 may be formed on a plurality of electrode pads 51, 52 provided on the substrate 50.

The adhesive layer 70 may be formed in the form of a film and may be attached to the first surface 50a of the substrate 50 by a lamination method. The adhesive layer 70 may have a thickness of about 1 μm to 10 μm. The adhesive layer 70 may be provided on and cover the electrode pads 51, 52 provided on the first surface 50a of the substrate 50 together with the solder 30.

The relay substrate 80 in which the first to third micro LEDs 110, 120, 130 are arranged may be aligned with respect to the substrate 50 so that the first to third micro LEDs 110, 120, 130 may be respectively transferred to a preset position of the substrate 50. In this case, the substrate 50 may be referred to as a target substrate because the first to third micro LEDs 110, 120, 130 are targeted to be transferred.

Light emitting surfaces of the first to third micro LEDs 110, 120, 130 may be temporarily attached to the bottom surface of the relay substrate 80, respectively. In this case, an adhesive for temporarily attaching the first to third micro LEDs 110, 120, 130 may be applied to the bottom surface of the relay substrate 80 or a thin film having an adhesive component may be formed on the bottom surface of the relay substrate 80.

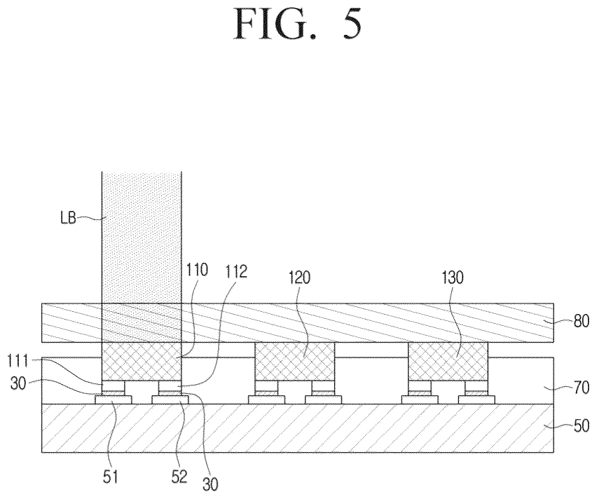

FIG. 5 is a diagram illustrating an example of transferring a micro LED arranged on a relay substrate to a substrate by a laser transfer method.

Referring to FIG. 5, in a state in which the relay substrate 80 aligned on the substrate 50 is in close contact with the substrate 50, a laser beam (LB) is emitted to the first micro LED 110.

When the first micro LED 110 is heated by laser beam (LB), a thin film having an adhesive or an adhesive component formed on the bottom surface of the relay substrate 80 may be heated by LB and melted. In this case, the first micro LED 110 may be separated from the bottom surface of the relay substrate 80.

The second and third micro LEDs 120, 130 may be separated from the bottom surface of the relay substrate 80 by a laser beam LB similar to the first micro LED 110.

The first to third micro LEDs 110, 120, 130 may be transferred to the substrate 50 by a laser transfer method, but embodiments are not limited thereto. For example, the first to third micro LEDs 110, 120, 130 may be transferred from the wafer or relay substrate 80 to the substrate 50 by a pick and place transfer method, a stamping transfer method, a rollable transfer method, or a fluid self-assembly transfer method.

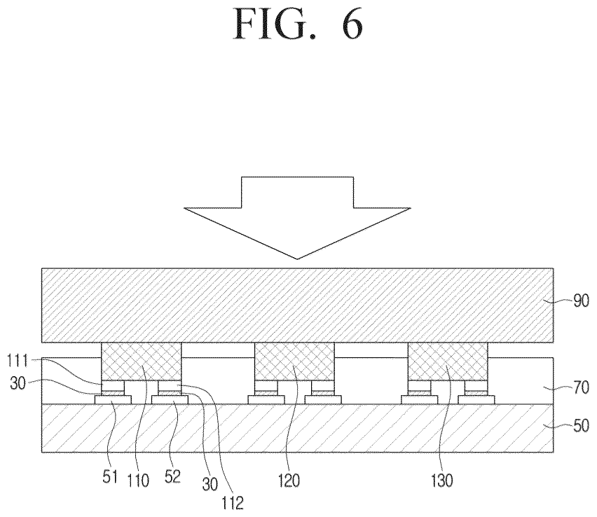

FIG. 6 is a diagram illustrating an example of thermally compressing a micro LED transferred to a substrate with a pressing member.

Referring to FIG. 6, the pressing member 90 may press the first to third micro LEDs 110, 120, 130 separated from the relay substrate 80. In this case, high temperature heat may be applied to the substrate 50 and the first to third LEDs 110, 120, 130.

When the first to third micro LEDs 110, 120, 130 are thermally compressed as described above, the solder 30 positioned between the electrodes 111, 112 provided on the first to third micro LEDs 110, 120, 130 and the electrode pads 51, 52 provided on the substrate 50 may be melted. In this case, the electrodes 111, 112 provided on the first to third micro LEDs 110, 120, 130 and the electrode pads 51, 52 provided on the substrate 50 may be physically and electrically connected to each other while metal bonding is performed by the solder 30.

The adhesive layer 70 may be phase decomposed to a non-conductive polymer resin and a flux agent by applied heat. In this case, the flux agent can improve wetting property of electrodes 111, 112 provided on the first to third micro LEDs 110, 120, 130. Accordingly, the solder 30 may be fused smoothly to the electrodes 111, 112 provided on the first to third micro LEDs 110, 120, 130 and the electrode pads 51, 52 provided on the substrate 50 while being melted during the thermal compression bonding.

The adhesive layer 70 may have fluidity while being melted by heat applied to the substrate 50. The adhesive layer 70 having fluidity may be introduced between the electrodes 111, 112 provided on the first to third micro LEDs 110, 120, 130 and may be introduced between the electrode pads 51, 52 provided on the substrate 50. Between the electrodes 111, 112 provided on the first to third micro LEDs 110, 120, 130 and between the electrode pads 51, 52 provided on the substrate 50 may be filled without voids by the adhesive layer 70.

After the above-described thermal compression bonding, when the adhesive layer 70 is cooled at room temperature or below room temperature or lower, the adhesive layer may be cured. Accordingly, the first to third micro LEDs 110, 120, 130 may be more firmly fixed to the substrate 50 by the cured adhesive layer 70.

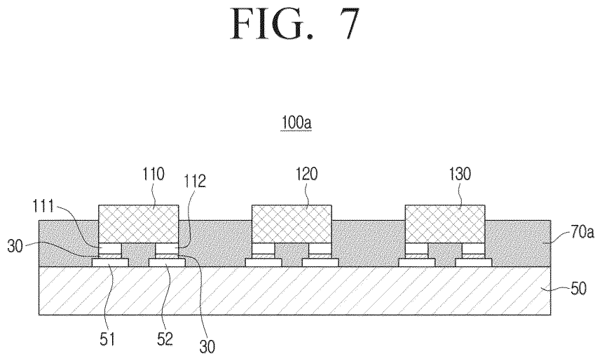

FIG. 7 is a schematic cross-sectional view of a pixel provided in a display module according to an embodiment of the disclosure.

The display module 100a according to an embodiment of the disclosure shown in FIG. 7 may be substantially the same as the display module 100 according to the embodiment of the disclosure illustrated in FIG. 3 except for the adhesive layer 70a. Accordingly redundant descriptions are omitted.

Referring to FIG. 7, the adhesive layer 70a may include a non-conductive polymer resin, a flux agent, and a pigment or dye having a black-based color. The adhesive layer 70a may be molded in a film shape.

The adhesive layer 70a may prevent light reflection by absorbing external light irradiated to the display module, and may minimize color mixing of different colors of light emitted from adjacent micro LEDs. Therefore, the adhesive layer 70a may improve the contrast ratio of the display module.

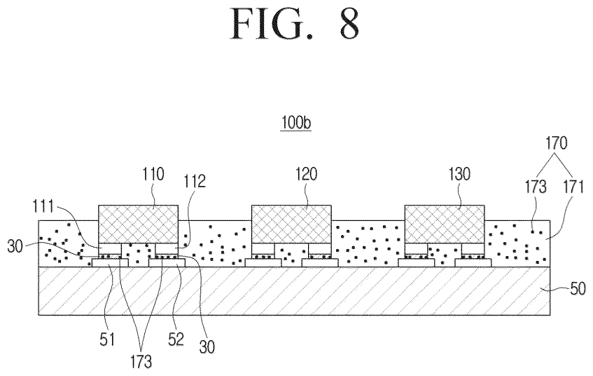

FIG. 8 is a schematic cross-sectional view of a pixel provided in a display module according to an embodiment of the disclosure.

The display module 100b according to an embodiment of the disclosure shown in FIG. 8 may be substantially the same as the display module 100 according to the embodiment of the disclosure illustrated in FIG. 3 except for the adhesive layer 170. Accordingly, redundant descriptions are omitted.

Referring to FIG. 8, the adhesive layer 170 may include a non-conductive polymer resin 171 including a flux agent, and a plurality of conductive particles 173. The adhesive layer 170 may be molded in a film shape.

The plurality of conductive particles 173 may be evenly distributed in the adhesive layer 170.

The conductive particles 173 around the solder 30 among the plurality of conductive particles 173 are melted during thermal compression bonding to electrically connect electrodes 111, 112 provided on the first to third micro LEDs 110, 120, 130 and electrode pads 51, 52 provided on the substrate 50 corresponding thereto together with the solder 30.

The plurality of conductive particles 173 may increase an electrical contact area between the electrodes 111, 112 provided on the first to third micro LEDs 110, 120, 130 and the electrode pads 51, 52 provided on the substrate 50 corresponding thereto, thereby improving a bonding yield.

The plurality of conductive particles 173 may have various sizes, for example, a size of about 10 nm to 1 μm according to the gap size of the bonding part and the height of the micro LED. Here, the gap size of the bonding part may be the interval between the electrodes 111, 112 provided on the first to third micro LEDs 110, 120, 130 and the electrode pads 51, 52 provided on the substrate 50 corresponding thereto, or the gap between the electrodes 111, 112 provided on the first to third micro LEDs 110, 120, 130 and the corresponding solder 30.

A plurality of conductive particles 173 in an amount about 0.1% to 5% of the entire adhesive layer 170 may be included in the adhesive layer 170 with respect to the entire adhesive layer 170 so as to prevent or minimize a short circuit between a pair of adjacent electrode pads 51, 52 and/or a short circuit between a pair of electrodes 111, 112 of an adjacent first micro LED 110.

The conductive particles 173 may include at least one of tin (Sn), indium (In), copper (Cu), silver (Ag), nickel (Ni), chromium (Cr), gold (Au), platinum (Pt).

The conductive particles 173 may be formed in a ball shape. In this case, the conductive particles 173 may be coated with a conductive film on the outer periphery of the core and the core. The core is a polymer resin having elasticity. The conductive layer may include gold (Au), copper (Cu), or tin (Sn).

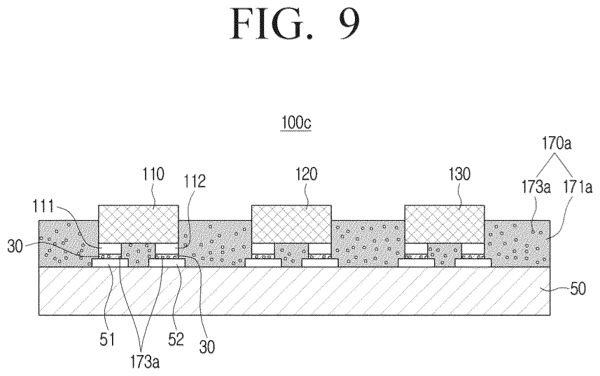

FIG. 9 is a schematic cross-sectional view of a pixel provided in a display module according to an embodiment of the disclosure.

The display module 100c according to an embodiment of the disclosure shown in FIG. 9 may be substantially the same as the display module 100b according to the embodiment of the disclosure illustrated in FIG. 8 except for the other components except for the adhesive layer 170a. Accordingly, redundant descriptions are omitted.

Referring to FIG. 9, the adhesive layer 170a may include a non-conductive polymer resin 171 a including a flux agent, a plurality of conductive particles 173a, and a pigment or dye having a black-based color. The adhesive layer 170a may be molded in a film shape.

The adhesive layer 170a may be substantially the same as the adhesive layer 170 illustrated in FIG. 8 in addition to a pigment or dye having a black-based color.

The adhesive layer 170a may prevent light reflection by absorbing external light irradiated to the display module, and may minimize color mixing of different colors of light emitted from adjacent micro LEDs. Therefore, the adhesive layer 170a may improve the contrast ratio of the display module.

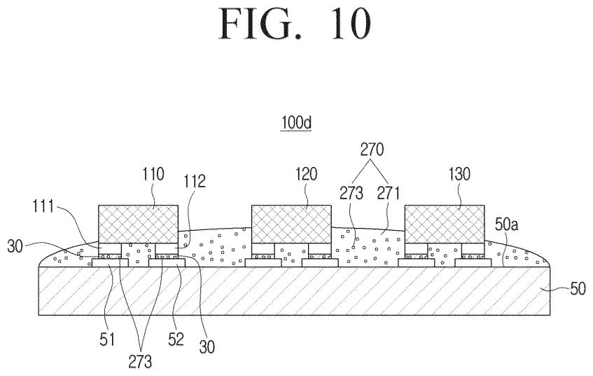

FIG. 10 is a schematic cross-sectional view of a pixel provided in a display module according to an embodiment of the disclosure.

The display module 100d according to an embodiment of the disclosure shown in FIG. 10 may be substantially the same as the display module 100b according to the embodiment of the disclosure illustrated in FIG. 8 except for the adhesive layer 270. Accordingly, redundant descriptions are omitted.

Referring to FIG. 10, the adhesive layer 270 may include a non-conductive polymer resin paste 271 in which a flux agent is mixed, and a plurality of conductive particles 273 dispersed in the non-conductive polymer resin paste 271.

The adhesive layer 270 may be formed in the form of a paste. The adhesive layer 270 may be applied to the first surface 50a of the substrate 50 to a predetermined thickness so as to cover the solder 30 and the electrode pads 51, 52 provided on the substrate 50 after the solder 30 is formed on the electrode pads 51, 52 provided on the substrate 50.

The plurality of conductive particles 273 may be formed to be substantially the same as the plurality of conductive particles 173 of FIG. 8.

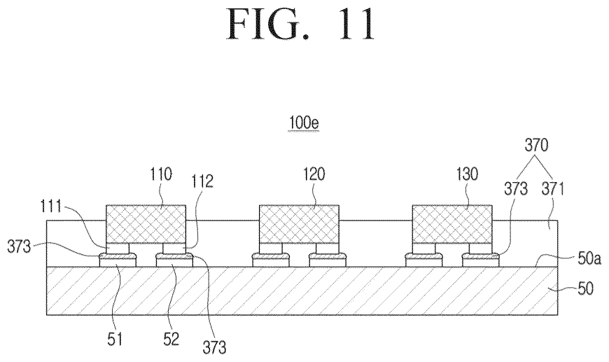

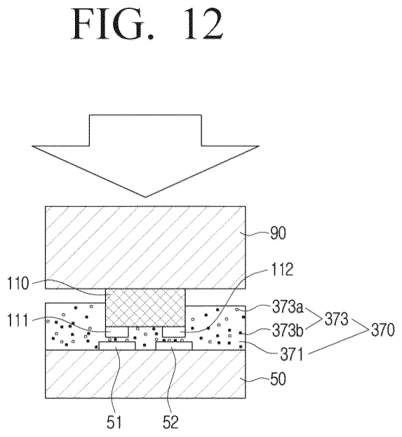

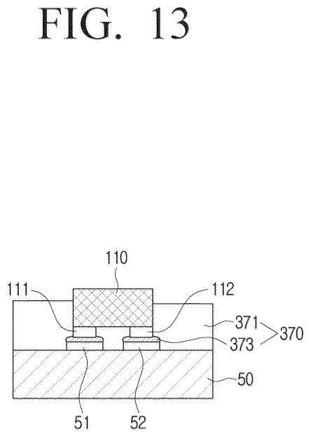

FIG. 11 is a schematic cross-sectional view of a pixel provided in a display module according to an embodiment of the disclosure. FIG. 12 is a diagram illustrating an example of thermally compressing a micro LED transferred to a substrate with a pressing member. FIG. 13 is a diagram illustrating an example in which first conductive particles and second conductive particles dispersed in an adhesive layer are collected between an electrode of a micro LED and an electrode pad of a substrate to form a solder.

The display module 100e according to an embodiment of the disclosure shown in FIG. 11 is similar to the display module 100b according to the embodiment of the disclosure illustrated in FIG. 8 and may be different from the display module 100b as to some configurations. Accordingly, redundant descriptions are omitted.

Hereinafter, in describing a display module according to an embodiment of the disclosure shown in FIG. 11, a configuration different from a display module according to an embodiment of the disclosure illustrated in FIG. 8 will be described.

Referring to FIG. 11, the adhesive layer 370 may include a non-conductive polymer resin 371, a flux agent, and a plurality of conductive particles 373.

The adhesive layer 370 may be formed in the form of a film. In this case, the adhesive layer 370 may be attached to the first surface 50a of the substrate 50 in a lamination manner.

The adhesive layer 370 is not limited to a film shape and may be formed in a paste state, for example. In this case, the adhesive layer 370 may be applied with a predetermined thickness on the first surface 50a of the substrate 50.

The non-conductive polymer resin 371 may be mixed with a flux agent. The non-conductive polymer resin 371 may include a pigment or dye having a black-based color together with a flux agent.

A plurality of conductive particles 373 may be evenly distributed in the non-conductive polymer resin 371. The plurality of conductive particles 373 may include first conductive particles 373a and second conductive particles 373b.

The first conductive particle 373a may be an alloy including at least one of tin (Sn), silver (Ag), copper (Cu), bismuth (Bi), and cobalt (Co).

The second conductive particles 373b may be made of a material substantially the same as or similar to the electrode pads 51, 52 provided on the substrate 50 and/or the electrodes 111, 112 provided on the first to third micro LEDs 110, 120, 130 so that the first conductive particles 373a may be well wet with the electrode pads 51, 52 provided on the substrate 50 and/or the electrodes 111, 112 provided on the first to third micro LEDs 110, 120, 130. The second conductive particles 373b may be made of, for example, gold (Au), copper (Cu), silver (Ag), or the like.

The plurality of first and second conductive particles 373a, 373b may have various sizes, for example, a size of about 10 nm to 1 μm according to the gap size of the bonding part and the height of the micro LED.

A plurality of conductive particles 373 may electrically connect electrodes 111, 112 provided on the first to third micro LEDs 110, 120, 130 and electrode pads 51, 52 provided on the substrate 50 respectively corresponding to the electrodes 111, 112 provided on the first to third micro LEDs 110, 120, 130 by self-assembly attached to electrode pads 51, 52 provided on the substrate 50 and/or electrodes 111, 112 provided on the first to third micro LEDs 110, 120, 130 in the non-conductive polymer resin 371 during thermal compression bonding.

Referring to FIG. 12, when the thermal compression bonding is performed, the first micro LED 110 transferred to the substrate 50 is pressed by a pressing member 90. In this case, relatively high-temperature heat may be applied to the substrate 50.

The non-conductive polymer resin 371 has fluidity while having a low viscosity due to relatively high-temperature heat. Accordingly, the plurality of first and second conductive particles 373a, 373b may move toward the electrode pads 51, 52 provided on the nearby substrate 50 and the electrodes 111, 112 provided on the first to third micro LEDs 110, 120, 130.

A plurality of first and second conductive particles 373a, 373b may have low wetting property with respect to other portions of the substrate 50 compared to high wetting property with respect to electrodes 51, 52 provided on the substrate 50 and electrodes 111, 112 provided on the first to third micro LEDs 110, 120, 130. Accordingly, attraction may be applied between the plurality of first and second conductive particles 373a, 373b and the electrode pads 51, 52 provided on the substrate 50 and between the electrodes 111, 112 provided on the first and second conductive particles 373a, 373b and the first to third micro LEDs 110, 120, 130, respectively.

A plurality of first and second conductive particles 373a, 373b may be attached to electrode pads 51, 52 provided on the substrate 50 and electrodes 111, 112 provided on the first to third micro LEDs 110, 120, 130. The first and second conductive particles 373a, 373b may gradually increase in volume and fill a gap between the electrode pads 51, 52 provided on the substrate 50 and the electrodes 111, 112 provided on the first to third micro LEDs 110, 120, 130.

A plurality of first and second conductive particles 373a, 373b between the electrode pads 51, 52 provided on the substrate 50 and the electrodes 111, 112 provided on the first to third micro LEDs 110, 120, 130 may be melted by a relatively high-temperature heat.

In this case, the plurality of first conductive particles 373a may be more smoothly fused to the electrode pads 51, 52 provided on the substrate 50 and the electrodes 111, 112 provided on the first to third micro LEDs 110, 120, 130 by a plurality of second conductive particles 373b made of a material similar to those of the electrode pads 51, 52 provided on the substrate 50 and the electrodes 111, 112 provided on the first to third micro LEDs 110, 120, 130.

Referring to FIG. 13, electrodes 111, 112 provided on the first to third micro LEDs 110, 120, 130 may form a stable physical connection with electrode pads 51, 52 provided on the substrate 50 by solder formed by agglomerating a plurality of conductive particles 373.

Also, the non-conductive polymer resin 371 of the adhesive layer 370 may more firmly support the physical connection between the electrodes 111, 112 provided on the first to third micro LEDs 110, 120, 130 and the electrode pads 51, 52 provided on the substrate 50.

While embodiments of the disclosure have been shown and described, the disclosure is not limited to the aforementioned embodiments, and it is apparent that various modifications may be made by those having ordinary skill in the technical field to which the disclosure belongs, without departing from the gist of the disclosure as claimed by the appended claims and their equivalents. Also, it is intended that such modifications are not to be interpreted independently from the technical idea or prospect of the disclosure.

What is claimed is:

1. A display assembly comprising:
a plurality of light emitting diodes;
a plurality of electrodes provided on the plurality of light emitting diodes;
a substrate;
a plurality of electrode pads provided on the substrate, the plurality of electrode pads being connected to the electrodes provided on the plurality of light emitting diodes; and
an adhesive layer fixing the plurality of light emitting diodes to the substrate,
wherein the adhesive layer comprises:
a non-conductive polymer resin;
a flux agent mixed with the non-conductive polymer resin; and
a plurality of conductive particles dispersed in the non-conductive polymer resin and connecting the electrodes of the light emitting diodes and the plurality of electrode pads.

2. The display assembly of claim 1, wherein the flux agent is made of a material that improves wetting property of the plurality of conductive particles.

3. The display assembly of claim 2, wherein the plurality of conductive particles comprise:
a plurality of first conductive particles; and
a plurality of second conductive particles having higher wetting property than the plurality of first conductive particles.

4. The display assembly of claim 3, wherein the plurality of first conductive particles comprise at least one of tin (Sn), silver (Ag), copper (Cu), bismuth (Bi), and cobalt (Co).

5. The display assembly of claim 3, wherein a material of the plurality of second conductive particles and one of a material of the electrodes provided on the plurality of light emitting diodes or a material of the plurality of electrode pads provided on the substrate, are same.

6. The display assembly of claim 5, wherein the second conductive particle is made of one of gold (Au), copper (Cu), and silver (Ag).

7. The display assembly of claim 1, wherein the plurality of conductive particles have size of 10 nm to 1 μm.

8. The display assembly of claim 1, wherein the adhesive layer further comprises a pigment or dye having a black-based color.

9. The display assembly of claim 1, wherein the adhesive layer is in a film shape.

10. The display assembly of claim 1, wherein the adhesive layer is in a paste shape.

11. A display device comprising:
a processor; and
a display assembly comprising:
a plurality of light emitting diodes;
a plurality of electrodes provided on the plurality of light emitting diodes;
a substrate;
a plurality of electrode pads provided on the substrate, the plurality of electrode pads being connected to the electrodes provided on the plurality of light emitting diodes; and
an adhesive layer fixing the plurality of light emitting diodes to the substrate,
wherein the adhesive layer comprises:
a non-conductive polymer resin;
a flux agent mixed with the non-conductive polymer resin; and
a plurality of conductive particles dispersed in the non-conductive polymer resin and connecting the electrodes of the light emitting diodes and the plurality of electrode pads.

12. The display device of claim 11, wherein the flux agent is made of a material that improves wetting property of the plurality of conductive particles.

13. The display device of claim 12, wherein the plurality of conductive particles comprise:
a plurality of first conductive particles; and
a plurality of second conductive particles having higher wetting property than the plurality of first conductive particles.

14. The display device of claim 13, wherein the plurality of first conductive particles comprise at least one of tin (Sn), silver (Ag), copper (Cu), bismuth (Bi), and cobalt (Co).

15. The display device of claim 13, wherein a material of the plurality of second conductive particles and one of a material of the electrodes provided on the plurality of light emitting diodes or a material of the plurality of electrode pads provided on the substrate, are same.

16. The display device of claim 15, wherein the second conductive particle is made of one of gold (Au), copper (Cu), and silver (Ag).

17. The display device of claim 1, wherein the plurality of conductive particles have size of 10 nm to 1 μm.

18. The display device of claim 11, wherein the adhesive layer further comprises a pigment or dye having a black-based color.

19. The display device of claim 11, wherein the adhesive layer is in a film shape.

20. The display assembly of claim 11, wherein the adhesive layer is in a paste shape.
